(19) United States
(12) Patent Application Publication
(10) Pub. No.: US 2025/0194069 A1
(43) Pub. Date: Jun. 12, 2025

(54) COMPONENT-MOUNTING MACHINE, COMPONENT-MOUNTING METHOD, AND CALIBRATION DEVICE FOR MOUNTING HEAD

(71) Applicant: FUJI CORPORATION, Chiryu (JP)

(72) Inventors: Yuji KAWASAKI, Nagoya-shi (JP); Kohei SUGIHARA, Nishio-shi (JP)

(73) Assignee: FUJI CORPORATION, Chiryu (JP)

(21) Appl. No.: 18/845,006

(22) PCT Filed: Mar. 25, 2022
(86) PCT No.: PCT/JP2022/014371

§ 371 Date: Sep. 9, 2024

(51) Int. Cl. H05K 13/08; H05K 13/04

(52) U.S. Cl. CPC H05K 13/0882; H05K 13/0409; H05K 13/041; H05K 13/089

(57) ABSTRACT

A component mounting machine includes a mounting head that supports a holding member capable of holding a component to be lifted and lowered and to be rotated about a central axis of the holding member, a storage section configured to store a correction value for each of multiple measurement angles set based on an error in a height direction when the holding member is moved to a specified height in a state of being indexed to the multiple measurement angles about the central axis, and a control section configured to correct a lowering amount of the holding member to a target height based on a pickup angle of the holding member indexed about the central axis and the correction value for each of the multiple measurement angles, in a pickup operation of picking up the component by the holding member.

### TECHNICAL FIELD

The present disclosure relates to a component mounting machine, a component-mounting method, and a calibration device for a mounting head.

### BACKGROUND ART

The component mounting machine is used to produce a board product. The component mounting machine picks up a component by, for example, a suction nozzle and mounts the component at a predetermined mounting position on the board. The component mounting machine includes a mounting head that is provided to be movable within the machine and supports the suction nozzle so that the suction nozzle can be lifted and lowered and can rotate. Patent Literature 1 discloses a configuration in which a correction value based on a result of calibration processing for a mounting head executed before production is reflected in a mounting process to absorb an individual difference in a configuration of the mounting head and to improve the accuracy of the mounting process.

### PATENT LITERATURE

Patent Literature 1: JP-A-2009-164276

### BRIEF SUMMARY

### Technical Problem

There is a demand for the component mounting machine to further improve production efficiency. Therefore, in the component mounting machine, it is required to appropriately reflect the result of the calibration processing for the mounting head in the mounting process and to prevent the occurrence of a mistake in a pickup operation or a mounting operation.

An object of the present description is to provide a component mounting machine, a component-mounting method, and a calibration device for a mounting head, which are capable of improving an accuracy of a mounting process and production efficiency by absorbing an individual difference in a configuration of the mounting head.

### Solution to Problem

The present description discloses a component mounting machine including a mounting head that supports a holding member capable of holding a component to be lifted and lowered and to be rotated about a central axis of the holding member, a storage section configured to store a correction value for each of multiple measurement angles set based on an error in a height direction when the holding member is moved to a specified height in a state of being indexed to the multiple measurement angles about the central axis, and a control section configured to correct a lowering amount of the holding member to a target height based on a pickup angle of the holding member indexed about the central axis and the correction value for each of the multiple measurement angles, in a pickup operation of picking up the component by the holding member.

### Advantageous Effects

According to such a configuration, the lowering amount to the target height of the holding member in the pickup operation is corrected depending on the pickup angle of the holding member. As a result, since the holding member is lowered to the target height with higher accuracy, the occurrence of a mistake in the pickup operation can be prevented. As a result, the accuracy of the mounting process and the production efficiency can be improved.

### BRIEF DESCRIPTION OF DRAWINGS

FIG. 1 is a plan view schematically illustrating a component mounting machine.

FIG. 2 is a top view schematically illustrating a mounting head.

FIG. 3 is a side view schematically illustrating the mounting head.

FIG. 4 is a view illustrating a suction nozzle and a component viewed in the direction IV in FIG. 3.

FIG. 5 is a plan view illustrating a supply region of a component in a bulk feeder.

FIG. 6 is a block diagram illustrating the component mounting machine and a calibration device.

FIG. 7 is a diagram illustrating, in an emphasized manner, an error in a height direction that may be generated due to the rotation of the suction nozzle about a central axis.

FIG. 8 is a flowchart illustrating calibration processing for the mounting head.

FIG. 9 is a table illustrating measurement values (errors in the height direction) and correction values in correction data.

FIG. 10 is a graph illustrating a relationship between an error in the height direction and a correction value for each measurement angle.

FIG. 11 is a flowchart illustrating a mounting process by the component mounting machine.

FIG. 12 is a flowchart illustrating a pickup cycle in the mounting process.

FIG. 13 is a view illustrating the lowering of the suction nozzle in a pickup operation.

FIG. 14 is a view illustrating the lifting of the suction nozzle in the pickup operation.

### DESCRIPTION OF EMBODIMENTS

A component mounting machine for executing a mounting process of a component, a component-mounting method, and a calibration device for a mounting head will be described with reference to the drawings.

### 1. Configuration of Component Mounting Machine 10

Component mounting machine 10 constitutes a production line for producing a board product, together with multiple types of board work machines including, for example, other component mounting machines 10. The board work machines constituting the production line described above may include a printer, an inspection device, a reflow oven, and the like.

### 1-1. Board Conveyance Device

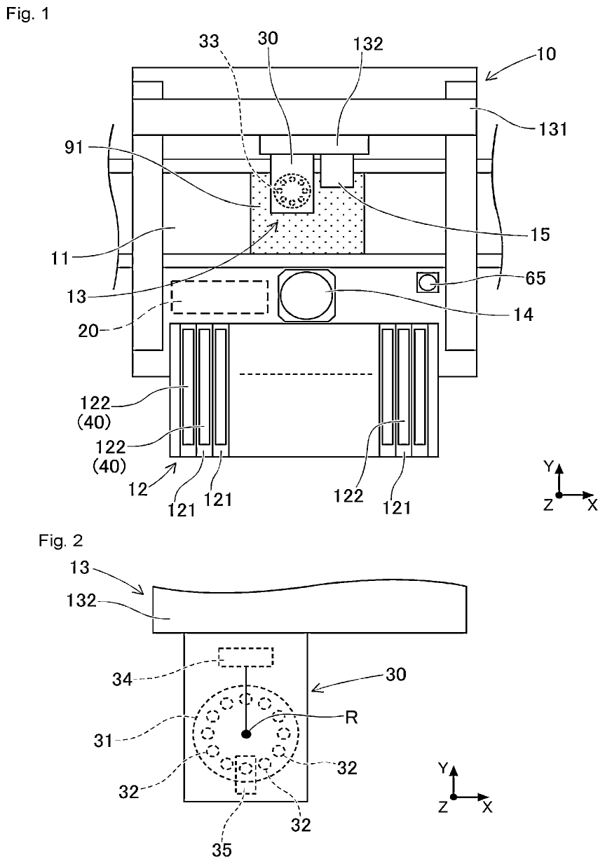

As illustrated in FIG. 1, component mounting machine 10 includes board conveyance device 11. Board conveyance device 11 subsequently conveys board 91 in a conveyance direction and positions board 91 at a predetermined position within the machine.

### 1-2. Component Supply Device 12

Component mounting machine 10 includes component supply device 12. Component supply device 12 supplies the component which is to be mounted on board 91. Component supply device 12 includes feeders 122 which are respectively provided in multiple slots 121. For example, a tape feeder that feeds and moves a carrier tape accommodating a large number of components to supply the components such that the components can be picked up is applied to feeder 122. In addition, bulk feeder 40 that supplies the components accommodated in a bulk state (loose state where each posture is irregular) such that the components can be picked up is applied to feeder 122. Details of bulk feeder 40 will be described below.

### 1-3. Component Transfer Device 13

Component mounting machine 10 includes component transfer device 13. Component transfer device 13 transfers the component supplied by component supply device 12 to the predetermined mounting position on board 91. Component transfer device 13 includes head driving device 131, moving table 132, and mounting head 30. Head driving device 131 moves moving table 132 in horizontal directions (X direction and Y direction) using a linear motion mechanism. Mounting head 30 is detachably fixed to moving table 132 by a clamp member (not illustrated), and is provided so as to be movable in the horizontal directions within the machine.

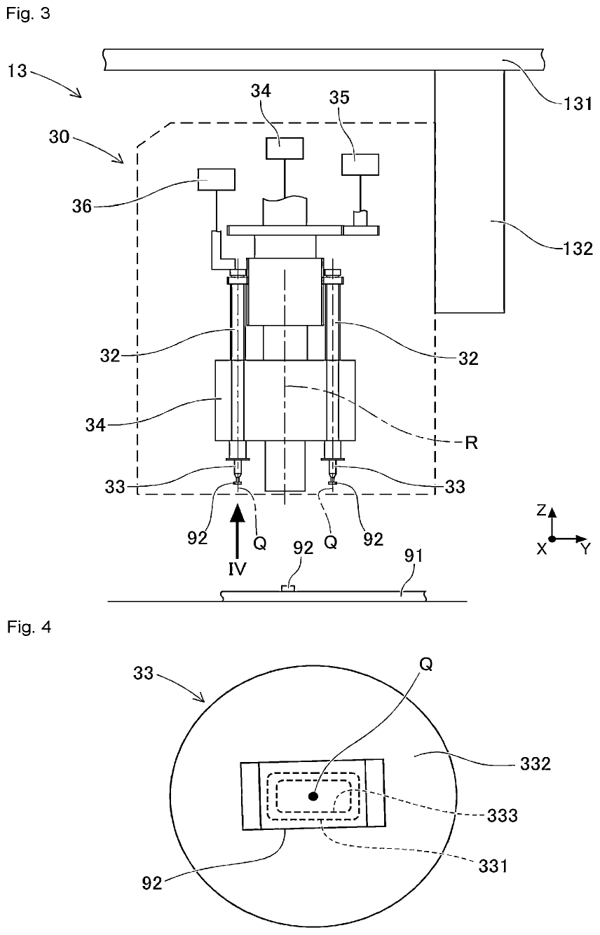

As illustrated in FIGS. 2 and 3, mounting head 30 has rotary head 31, which is provided so as to rotate about an R axis parallel to a vertical axis (Z axis). Rotary head 31 supports multiple holders 32 to be lifted and lowered and to be rotated about a central axis (Q axis) for each of multiple holders 32. A holding member that holds component 92 is attached to each of multiple holders 32. In the present embodiment, the holding member is suction nozzle 33 that holds component 92 by picking up using supplied negative pressure air. A chuck or the like that holds the component by gripping the component may be adopted as the holding member.

Suction nozzle 33 has cylindrical shaft portion 331 extending in the central axis direction. Flange 332 is fixed to shaft portion 331. Flange 332 is a part that is a background when suction nozzle 33 is imaged from below. Shaft portion 331 has opening 333 formed in a lower tip end portion. The tip end portion (shaft portion 331 and opening 333) of suction nozzle 33 may be formed in a non-circular shape as illustrated in FIG. 4, in addition to being formed in a concentric circular shape as viewed in the central axis direction.

As described above, suction nozzle 33 in which the tip end portion is formed in a non-circular shape is applied to the mounting process for the purpose of ensuring a larger area (area of opening 333) where a pickup force by suction acts on the upper surface of the rectangular fine chip component. As described above, when opening 333 extends beyond the outer edge of component 92, since negative pressure air leaks and the pickup force by suction decreases, non-circular suction nozzle 33 is used such that the longitudinal direction of opening 333 substantially coincides with the longitudinal direction of component 92 in the pickup operation.

Mounting head 30 includes R-axis rotation device 34 that rotates rotary head 31 about the R axis. R-axis rotation device 34 determines the angle of rotary head 31 at a predetermined angle about the R axis to index to a lifting and lowering position where first holder 32 is lifted and lowered by lifting and lowering device 36 described later. Mounting head 30 includes Q-axis rotation device 35 that rotates holder 32 about the Q axis. In the present embodiment, Q-axis rotation device 35 has a mechanism that rotates multiple holders 32 in an interlocked fashion and is used in common to rotate multiple holders 32. With the configuration described above, when first holder 32 is angled at a predetermined angle about the Q axis, second multiple holders 32 are also angled at a predetermined angle in the interlocked fashion.

Mounting head 30 has lifting and lowering device 36 that lifts and lowers one holder 32 in multiple holders 32, which is indexed to the lifting and lowering position by the rotation of rotary head 31. Lifting and lowering device 36 lifts and lowers holder 32 to lift and lower suction nozzle 33 attached to holder 32. Mounting head 30 may adopt a configuration in which two or more lifting and lowering positions are provided, and multiple lifting and lowering devices are provided that can be independently driven such that holders 32 positioned at the respective positions can be lifted and lowered.

The number of holders 32 supported by mounting head 30 having the configuration as described above may vary depending on the type of mounting head 30. In addition, mounting head 30 may adopt various aspects other than an aspect in which multiple holders 32 are supported at equal intervals in an annular shape as the present embodiment. For example, mounting head 30 may adopt an aspect in which multiple holders 32 are supported, which are arranged in a straight line or a matrix.

### 1-4. Part Camera 14 and Board Camera 15

Component mounting machine 10 includes part camera 14 and board camera 15. Part camera 14 and board camera 15 are digital imaging devices having an imaging element such as CMOS. Part camera 14 and board camera 15 capture an image based on a control signal and transmit image data acquired by the imaging. Part camera 14 is configured to be able to image a component held by suction nozzle 33 from below. Board camera 15 is provided on moving table 132 so as to be movable in the horizontal directions integrally with mounting head 30. Board camera 15 is configured to be able to capture an image of board 91 from above.

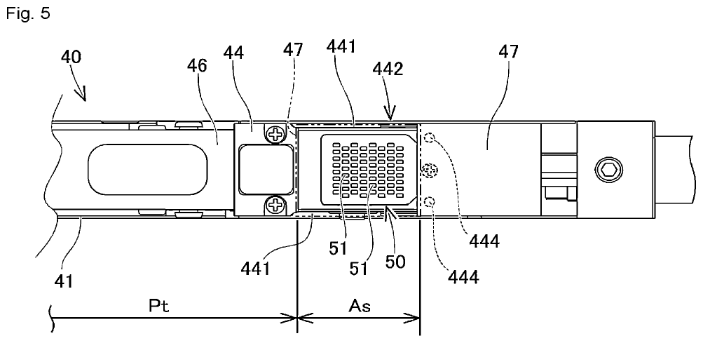

In addition, board camera 15 can use various devices or the like as an imaging target within the movable range of moving table 132 in addition to using the surface of board 91 as an imaging target. For example, in the present embodiment, board camera 15 can capture an image of supply region As to which bulk feeder 40 supplies the component or fiducial mark 444 provided on an upper part of bulk feeder 40 within the camera field of view (refer to FIG. 5). As described above, board camera 15 may be used commonly to capture images for different imaging targets in order to acquire image data used for various image processing.

### 1-5. Control Device 20

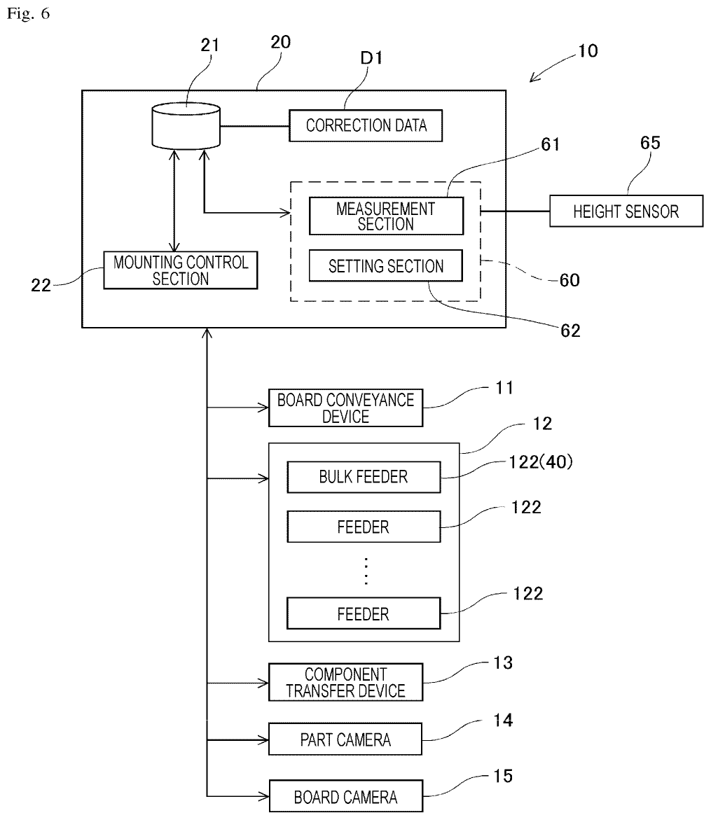

Component mounting machine 10 includes control device 20, as illustrated in FIG. 1. Control device 20 includes mainly of CPU, various types of memory, and a control circuit. Control device 20 includes storage section 21 as illustrated in FIG. 6. Storage section 21 includes an optical drive device such as a hard disk device or a flash memory. Various data such as control program and correction data D1 used for controlling the mounting process are stored in storage section 21 of control device 20.

The control program indicates the mounting position, the mounting angle, and the component type of the component to be mounted on board 91 in the mounting process in the scheduled mounting order. Here, the mounting process includes a process of repeating a pick-and-place cycle (PP cycle), which includes a pickup cycle and a mounting cycle, multiple times. The term “pickup cycle” described above is a process of repeating a pickup operation of picking up the component supplied from component supply device 12 by suction nozzle 33 multiple times.

In addition, the term “mounting cycle” described above is a process of repeating a mounting operation of mounting the picked-up component at a predetermined mounting position in board 91 at a predetermined mounting angle multiple times. As described above, in the control program, an execution order of the PP cycle including multiple pickup operations and mounting operations grouped in consideration of the number of suction nozzles 33 supported by mounting head 30, the movement distance of mounting head 30, and the like is set in advance.

Control device 20 includes mounting control section 22. Mounting control section 22 executes the mounting process based on the control program in which the execution order of the PP cycles is set. Mounting control section 22 executes recognition processing of a holding state of the component held by each of multiple holding members (suction nozzles 33). Specifically, mounting control section 22 executes the image processing on image data acquired through imaging of part camera 14 to recognize the position and angle of each component with respect to a reference position of mounting head 30. Mounting control section 22 may execute the image processing on the image data acquired by imaging the component from a side, below, or above using, for example, a head camera unit provided integrally with mounting head 30 in addition to part camera 14.

In the mounting process, mounting control section 22 controls the operation of mounting head 30 based on information output from various sensors, the result of the image processing, a control program, or the like. As a result, the positions and the angles of multiple suction nozzles 33 supported by mounting head 30 are controlled. As a result, the component held by suction nozzle 33 is mounted at a predetermined mounting position instructed by the control program at a predetermined mounting angle.

Control device 20 recognizes the supply states of multiple components in supply region As of bulk feeder 40 based on the image data acquired by the imaging of the camera (in the present embodiment, board camera 15). Recognition processing of the supply state includes a processing of recognizing whether there is the component that can be picked up in supply region As and recognizing the position and the angle of the component, in a case where there is the component that can be picked up. Mounting control section 22 controls an operation of mounting head 30 in the pickup operation based on a result of the recognition processing of the supply state.

In addition, control device 20 controls the component supply by component supply device 12. In a case where bulk feeder 40 is installed in component supply device 12, control device 20 causes such that the supply operation by bulk feeder 40 is executed at an appropriate execution timing during the execution of the mounting process.

### 2. Configuration of Bulk Feeder 40

Bulk feeder 40 is installed in component mounting machine 10 and functions as a part of component supply device 12. Bulk feeder 40 supplies components 92 which are accommodated in a bulk state where components 92 are not aligned like a carrier tape. As a result, unlike a tape feeder, since bulk feeder 40 does not use a carrier tape, bulk feeder 40 has the advantage that loading of the carrier tape, collection of a used carrier tape, and the like can be omitted.

For example, there is bulk feeder 40 of a type that supplies components 92 in irregular postures to planar supply region As. However, when components 92 are so close to one another to contact, components 92 are accumulated (a state of being overlapped in the vertical direction), or component 92 is in a horizontally standing posture in which the width direction is directed in the vertical direction in supply region As, component mounting machine 10 cannot regard these components 92 as a pickup target. Then, in order to increase the ratio of components 92 that can be picked up, there is bulk feeder 40 of a type that supplies components 92 in an aligned state to supply region As. In the present embodiment, bulk feeder 40 of this type in which components 92 are aligned will be described as an example.

When bulk feeder 40 is set in slot 121 of component supply device 12, bulk feeder 40 is supplied with power via a connector, and is in a state capable of communicating with control device 20. Bulk feeder 40 includes feeder main body 41 having a flat box shape. A component case for accommodating multiple components 92 in a bulk state is detachably attached to feeder main body 41. Bulk feeder 40 includes trajectory member 44 that is provided to be capable of vibrating with respect to feeder main body 41. Trajectory member 44 is formed with conveyance path Pt along which multiple components 92 are conveyed and supply region As communicating with conveyance path Pt and is open upwards such that multiple components 92 can be picked up.

Trajectory member 44 is formed so as to extend in the front-rear direction (left-right direction in FIG. 5) of feeder main body 41. A pair of side walls 441, which projects upwards, is formed along both edges in a width direction (vertical direction in FIG. 5) of trajectory member 44. A pair of side walls 441 surrounds a circumferential edge of conveyance path Pt together with tip end portion 442 of trajectory member 44 to prevent components 92 conveyed along conveyance path Pt from leaking. A pair of left and right circular fiducial marks 444 each indicating a reference position of supply region As is affixed to an upper surface of tip end portion 442.

In the present embodiment, alignment member 50 is exchangeably attached to trajectory member 44. Alignment member 50 has multiple cavities 51 that individually accommodate multiple components 92. Specifically, multiple cavities 51 are arranged in a zigzag shape in which rows adjacent to each other are staggered in the conveyance direction in supply region As. For example, alignment member 50 has a total of 64 cavities 51 that are regularly arranged in eight cavities in the conveyance direction and eight cavities in the width direction of conveyance path Pt. Each of multiple cavities 51 is open upwards to accommodate component 92 in a posture in which the thickness direction of component 92 is directed in the vertical direction. Multiple cavities 51 may be arranged in a matrix.

The opening of cavity 51 is set to a dimension slightly larger than the outer shape of component 92 in an upward view. The depth of cavity 51 is set according to the type (shape, mass, and the like) of component 92. One selected based on the type of component 92, the required number of cavities 51, and functionality from various types of trajectory members 44 is attached to trajectory member 44.

Here, the term “supply region As” of trajectory member 44 is a region to which components 92 are supplied in a bulk state and a region where component 92 can be picked up by suction nozzle 33 supported by mounting head 30. In addition, the term “conveyance path Pt” of trajectory member 44 is a path of component 92 along which component 92 moved from the component case side to trajectory member 44 is conveyed to supply region As. Cover 46 that covers the upper part of conveyance path Pt is fixed to trajectory member 44.

Bulk feeder 40 includes shutter 47 which is provided on an upper part of trajectory member 44 and is capable of opening and closing an opening of supply region As. By opening or closing shutter 47, bulk feeder 40 can prevent component 92 from protruding and foreign matters from entering supply region As. Bulk feeder 40 includes a vibration device (not illustrated) provided in feeder main body 41. The vibration device applies vibration to trajectory member 44 so that multiple components 92 are conveyed along conveyance path Pt. When the vibration device applies vibration to trajectory member 44, trajectory member 44 performs an elliptical motion in a side view: As a result, a forward and upward external force or a rearward and upward external force is applied to multiple components 92 at conveyance path Pt according to a rotational direction of the elliptical motion of trajectory member 44.

As a result, each of multiple components 92 is conveyed to the front side or conveyed to the rear side of trajectory member 44, and is accommodated in multiple cavities 51, and thus multiple components 92 are supplied to be picked up. A supply process of component 92 using the above-described vibration device is appropriately executed according to a command from control device 20.

### 3. Calibration Device 60 for Mounting Head 30

### 3-1. Overview and Configuration of Calibration Device 60

Calibration device 60 executes the calibration processing for mounting head 30 as a target before execution of the mounting process. The calibration processing is performed for the purpose of obtaining an individual difference in the configuration of mounting head 30 and acquiring an appropriate correction value according to the operation condition and the operation state before execution of the mounting process. The “individual difference” described above includes, for example, the mounting error of moving table 132 and mounting head 30, and the operation characteristics of R-axis rotation device 34, Q-axis rotation device 35, and lifting and lowering device 36 of mounting head 30.

As a result, for example, in a case where mounting head 30 lowers predetermined suction nozzle 33 to a predetermined target height, a difference (height error) may occur between the actual height of the tip end portion and the Z value (actual height) in the control. Furthermore, as in the present embodiment, in the configuration in which mounting head 30 includes multiple holders 32 that support each of suction nozzles 33, different height errors may occur for each of multiple holders 32.

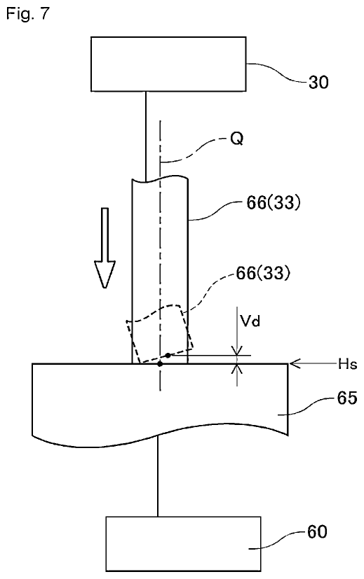

Then, as illustrated in FIG. 7, for example, calibration device 60 causes multiple holders 32 to support measurement jig nozzle 66, and gradually lowers jig nozzle 66 from above toward height sensor 65. Height sensor 65 is installed inside component mounting machine 10 such that a detection section is at specified height Hs. Jig nozzle 66 is a dummy imitating suction nozzle 33. Height sensor 65 transmits a detection signal to calibration device 60 when a test object (jig nozzle) comes into contact with the detection section. Calibration device 60 measures the difference between the actual height of the jig nozzle when the detection signal is input and specified height Hs of the detection section as the height error of holder 32.

By obtaining the height error for each of multiple holders 32 as described above, the command value in the height direction can be corrected so as to cancel the height error. As a result, control device 20 can control the lifting and lowering of holder 32 and suction nozzle 33 in the pickup operation and the mounting operation with higher accuracy. In the calibration processing described above, each of multiple holders 32 is caused to have a predetermined angle (for example, 0 degrees) about the Q axis.

Here, when holder 32 is indexed at an angle different from the predetermined angle in the pickup operation or the mounting operation, the height error described above may vary. As illustrated in an exaggerated manner by the broken line in FIG. 7, this is because the height error may vary due to the fact that holder 32 is slightly curved or the central axis (Q axis) of holder 32 is slightly inclined with respect to the vertical axis. Such a difference in the height error for each indexed angle of holder 32 can be made such that a sliding portion of suction nozzle 33 is operated by pushing suction nozzle 33 toward board 91 in the mounting operation, for example, and the mounting operation is not affected.

However, in a case where the height of suction nozzle 33 in the pickup operation or the mounting operation is controlled with high accuracy, the difference in the height error for each indexed angle of holder 32 as described above may affect it. Then, in the present embodiment, in order to improve the accuracy of the mounting process and prevent the occurrence of the pickup mistake, component mounting machine 10 adopts a configuration in which the calibration processing is performed by calibration device 60 having the following configuration, and the mounting process is executed using the result of the calibration processing. Calibration device 60 includes measurement section 61 and setting section 62.

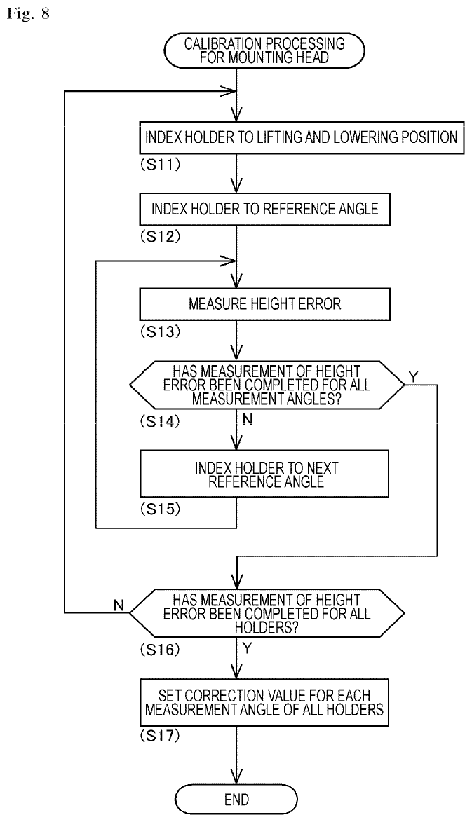

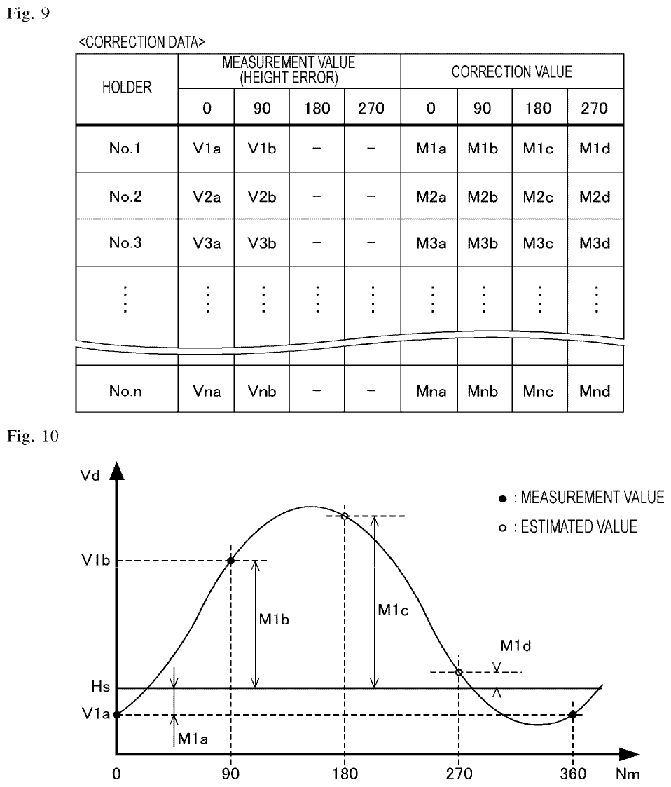

In the calibration processing (refer to FIG. 8) of mounting head 30, measurement section 61 measures an error (height error Vd) in the height direction when the holding member (including jig nozzle 66) is moved to specified height Hs in a state of being indexed to multiple measurement angles about the central axis (Q axis). In addition, setting section 62 sets correction value Mc for each of the multiple measurement angles based on height error Vd (refer to FIGS. 9 and 10). Correction value Mc set by setting section 62 is stored in storage section 21 of control device 20 as correction data D1.

### 3-2. Calibration Processing by Calibration Device 60

The calibration processing of mounting head 30 will be described in detail with reference to FIGS. 8 to 10. In preparation for the calibration processing, it is assumed that measurement jig nozzles 66 as the holding members are attached to multiple holders 32. In addition, it is assumed that mounting head 30 is positioned such that jig nozzle 66 at the lifting and lowering position of mounting head 30 is positioned above height sensor 65.

As illustrated in FIG. 8, first, calibration device 60 indexes predetermined holder 32 of multiple holders 32 of mounting head 30 to the lifting and lowering position by the rotation of rotary head 31 about the R axis (S11). Next, calibration device 60 rotates holder 32 about the Q axis to index to reference angle Ns (S12). Reference angle Ns is initial measurement angle Nm in the calibration processing, and is set to 0 degrees in the present embodiment.

Subsequently, measurement section 61 measures height error Vd (S13). Specifically, measurement section 61 gradually lowers holder 32 and jig nozzle 66 from above toward height sensor 65. When the test object (jig nozzle 66) comes into contact with the detection section of height sensor 65 and the detection signal is input from height sensor 65, measurement section 61 causes holder 32 and jig nozzle 66 to lift to the original initial height. Measurement section 61 measures the difference between the actual height (Z value) of jig nozzle 66 when the detection signal is input and specified height Hs of the detection section as height error Vd of holder 32.

When the measurement of height error Vd has not been completed for all measurement angles Nm set in advance in holder 32 as the measurement target (S14: No), calibration device 60 rotates holder 32 about the Q axis to index to next measurement angle Nm (S15). Next measurement angle Nm is set to an angle rotated by 90 degrees from reference angle Ns, for example. Measurement section 61 measures height error Vd again (S13). As a result, measurement section 61 measures height error Vd of holder 32 in changed measurement angle Nm. In other words, measurement section 61 measures height error Vd when the holding member (jig nozzle 66) is moved to specified height Hs in a state of being indexed at multiple measurement angles Nm about the central axis (Q axis).

When the measurement of height error Vd has been completed for all measurement angles Nm (for example, 0 degrees and 90 degrees) set in advance in holder 32 as the measurement target (S15: Yes), calibration device 60 determines whether the measurement of height error Vd has been completed for all holders 32 as the measurement target (S16). When there is unmeasured holder 32 (S16: No), calibration device 60 repeatedly executes measurement processing (S11 to S15). When all the measurement processing scheduled to be executed has been completed (S16: Yes), setting section 62 sets correction value Mc for each measurement angle Nm of all holders 32 (S17).

Specifically, as illustrated in FIG. 9, height error Vd (V1a, V1b, V2a, V2b, and the like) for each of multiple measurement angles Nm (0 degrees, 90 degrees) of holder 32 (No. 1. No. 2, and the like) as the measurement target is acquired by the measurement processing (S11 to S15) described above. As illustrated in FIG. 10, setting section 62 sets correction value Mc (M1a, M1b) for canceling height error Vd (V1a, V1b) for each of multiple measurement angles Nm (0 degrees, 90 degrees) of first holder 32 (No. 1), for example. In other words, setting section 62 sets lowering amount Ud that cancels out height error Vd when the holding member (suction nozzle 33) is lowered to the target height (pickup height, mounting height) in the mounting process as correction value Mc (M1a, M1b). Storage section 21 stores correction value Mc for each of the multiple holding members (suction nozzles 33) and each of multiple measurement angles Nm.

In addition, setting section 62 may set correction value Mc at an angle different from measurement angle Nm in setting processing (S17) of correction value Mc. For example, setting section 62 calculates estimated height error Ve (V1c, V1d) at another angle based on height error Vd (V1a, V1b) and the error characteristics which are actual measurement values. For example, the term “error characteristics” described above indicates that the relationship between measurement angle Nm and multiple height errors Vd can be approximated to a sinusoidal waveform, the maximum value and the minimum value of height error Vd, and the extent of the difference therebetween.

### 4. Mounting Process by Component mounting machine 10

### 4-1. Overview of Mounting Process

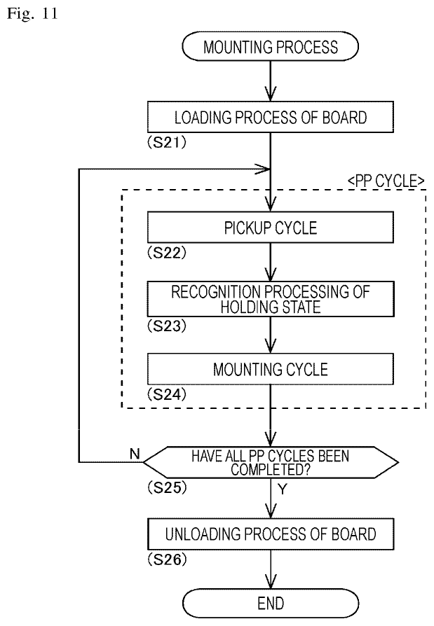

With reference to FIG. 11, the mounting process by component mounting machine 10 will be described. Here, it is assumed that bulk feeder 40 is installed in component supply device 12. In the mounting process, first, as illustrated in FIG. 11, board conveyance device 11 of component mounting machine 10 performs a loading process of board 91 (S21). As a result, board 91 is loaded into the machine and positioned at a predetermined position within the machine.

Next, control device 20 executes the PP cycle. In the PP cycle, mounting control section 22 executes the pickup cycle in which the pickup operation of picking up component 92 is repeated using multiple suction nozzles 33 (S22). In this case, mounting control section 22 causes the operation of mounting head 30 in the pickup operation to subsequently position mounting head 30 according to the position of component 92 that can be picked up. In addition, in a case where bulk feeder 40 supplies component 92 as the pickup target, mounting control section 22 appropriately switches the coordinate value that is the center of cavity 51 and the coordinate value of the reference position of component 92 as the position of component 92 that can be picked up, and positions suction nozzle 33.

Furthermore, in the pickup cycle (S22), mounting control section 22 executes processing of correcting lowering amount Ud of suction nozzle 33 based on correction data D1 as necessary. Details of the pickup cycle including correction processing of lowering amount Ud will be described later.

Subsequently, control device 20 executes the recognition processing of the holding state of components 92 held by multiple suction nozzles 33 (S23). Specifically, control device 20 moves mounting head 30 above part camera 14 and transmits an imaging command to part camera 14. Control device 20 executes the image processing on the image data acquired by the imaging of part camera 14 to recognize the posture (position and angle) of component 92 held by each of multiple suction nozzles 33. The result of the recognition processing of the holding state (S23) is recorded in storage section 21 as an operation result indicating whether the pickup mistake occurs in the pickup operation.

Thereafter, control device 20 executes the mounting cycle in which the mounting operation of mounting the component is repeated using multiple suction nozzles 33 (S24). In the mounting operation of the mounting cycle (S24), control device 20) causes the operation of mounting head 30 to mount each of components 92 at the mounting positions designated by the control program. Furthermore, mounting head 30 controls the operation of mounting head 30 such that suction nozzle 33 is positioned and angled with respect to the mounting position based on the result of the recognition processing (S23).

Control device 20 determines whether all the PP cycles have been completed based on the control program (S25). When all the PP cycles have not been completed (S25: No), the PP cycle (S22 to S24) is executed. When all the PP cycles have been completed (S25: Yes), control device 20 executes an unloading process of board 91 (S26). In the unloading process of board 91, board conveyance device 11 unclamps board 91 which is positioned and unloads board 91 outside component mounting machine 10.

### 4-2. Details of Pickup Cycle

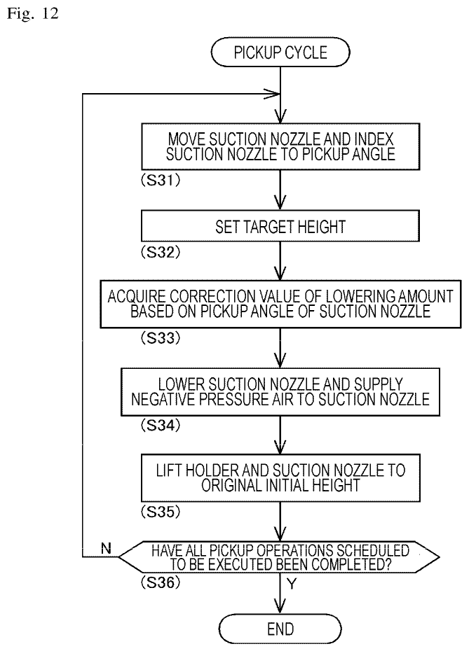

Details of the pickup cycle (S22) in the mounting process will be described with reference to FIGS. 12 to 14. In the mounting cycle, mounting control section 22 first moves predetermined suction nozzle 33 above component 92 as the pickup target, and indexes suction nozzle 33 to predetermined pickup angle Np (S31). Specifically, predetermined suction nozzle 33 is indexed to the lifting and lowering position by rotation of rotary head 31 about the R axis, and is rotated about the central axis (Q axis) to set pickup angle Np. For example, pickup angle Np is an angle at which the longitudinal direction of the tip end portion formed in the non-circular shape of suction nozzle 33 coincides with the longitudinal direction of cavity 51 of bulk feeder 40 or the longitudinal direction of component 92.

Next, mounting control section 22 sets target height Ht (S32). Target height Ht described above is the height of a lowered end of suction nozzle 33 that is lowered to pick up component 92 as the pickup target. In the present embodiment, in a case where feeder 122 that supplies component 92 as the pickup target is bulk feeder 40, mounting control section 22 attempts to perform the aerial pickup such that component 92 is not pressed downward in the series of pickup operations, that is, the sliding portion of suction nozzle 33 is not operated. This is a control for preventing an impact when suction nozzle 33 comes into contact with the upper surface of component 92 from affecting component 92 accommodated in another cavity 51.

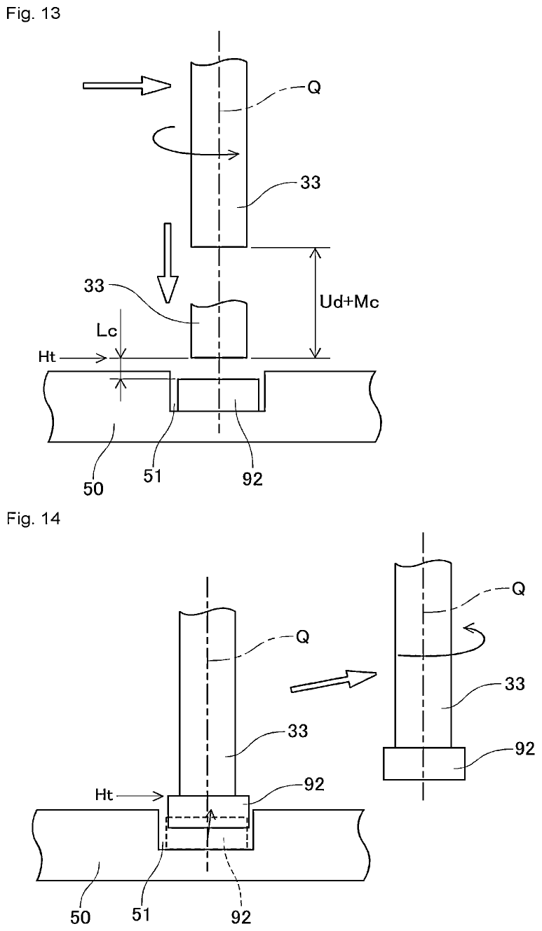

Specifically, in the pickup operation, as illustrated in FIG. 13, mounting control section 22 sets the height at which predetermined clearance Lc is provided from the upper surface of supplied component 92 as target height Ht. That is, mounting control section 22 sets target height Ht such that the tip end portion of suction nozzle 33 which has reached the lowered end to pick up component 92 is positioned above the upper surface of component 92 accommodated in cavity 51. Mounting control section 22 acquires lowering amount Ud from the current height of suction nozzle 33 based on target height Ht.

Subsequently, mounting control section 22 acquires correction value Mc of lowering amount Ud based on pickup angle Np of suction nozzle 33 (S33). Specifically, for example, in a case where pickup angle Np is 90 degrees, mounting control section 22 acquires correction value Mc (M1b) calculated based on height error Vd (V1d) of 90 degrees in measurement angle Nm of first holder 32 that supports predetermined suction nozzle 33 in correction data D1. In a case where correction value Mc of measurement angle Nm matching pickup angle Np is not included in correction data D1, mounting control section 22 may acquire correction value Mc of measurement angle Nm closest to pickup angle Np or may estimate and acquire correction value Mc depending on pickup angle Np.

Mounting control section 22 corrects lowering amount Ud of suction nozzle 33 based on acquired correction value Mc, lowers suction nozzle 33, and supplies negative pressure air to suction nozzle 33 (S34). As a result, the tip end portion of suction nozzle 33 is lowered to target height Ht by lowering amount Ud in which correction value Mc for canceling height error Vd is reflected. As illustrated in FIG. 14, component 92 as the pickup target is sucked by the negative pressure air when suction nozzle 33 approaches. As described above, mounting control section 22 sucks and picks up component 92 by causing suction nozzle 33 to approach target height Ht. In this case, the sliding portion of suction nozzle 33 does not operate, and the occurrence of an impact due to the pickup operation is prevented.

When suction nozzle 33 is lowered to target height Ht, mounting control section 22 lifts holder 32 and suction nozzle 33 to the original initial height (S35). When all the pickup operations scheduled to be executed have not been completed (S36: No), mounting control section 22 repeatedly executes the pickup operation described above (S31 to S35). When all the pickup operations have been completed (S36: Yes), mounting control section 22 ends the current pickup cycle.

In the pickup cycle (S22) as described above, only in a case where feeder 122 that supplies component 92 as the pickup target is bulk feeder 40, the pickup operation of the aerial pickup described above may be attempted, and in a case of a tape feeder, the operation may be switched to a normal pickup operation (an operation of pressing against component 92 such that the sliding portion of suction nozzle 33 operates). Furthermore, even in a case where bulk feeder 40 supplies component 92 as the pickup target, for example, in a case where the supply operation of component 92 is scheduled to be executed immediately after the pickup operation, a normal pickup operation may be performed. In addition, in the pickup operation of the aerial pickup, the lowering speed or the deceleration of suction nozzle 33 may be caused to be reduced as compared with the normal pickup operation.

According to the configuration of component mounting machine 10 and the component-mounting method (FIG. 11 to FIG. 12), lowering amount Ud to target height Ht of suction nozzle 33 in the pickup operation is corrected depending on pickup angle Np of suction nozzle 33. As a result, since suction nozzle 33 is lowered to target height Ht with higher accuracy, the occurrence of a mistake in the pickup operation can be prevented. As a result, the accuracy of the mounting process and the production efficiency can be improved.

### 5. Modification Aspect of Embodiment

In the embodiment, in a case where the aerial pickup is attempted in the pickup operation, lowering amount Ud is corrected depending on pickup angle Np of suction nozzle 33. On the other hand, by correcting lowering amount Ud for each of pickup angle Np even in the normal pickup operation, suction nozzle 33 can be positioned at target height Ht with higher accuracy. As a result, it is possible to prevent the occurrence of a pickup mistake and to reduce the impact that may be generated with the pickup operation.

In addition, in the embodiment, an aspect in which the control of correcting lowering amount Ud depending on the angle of suction nozzle 33 about the central axis (Q axis) is applied to the pickup operation has been described as an example. On the other hand, control for correcting lowering amount Ud may be applied to the mounting operation. As a result, the lowering of suction nozzle 33 to the target height with respect to board 91 is performed with higher accuracy, and it is possible to prevent the occurrence of a mounting mistake and to reduce the impact that may be generated with the mounting operation.

In the embodiment, the holding member that holds component 92 is suction nozzle 33 that picks up and holds component 92 by the negative pressure air. On the other hand, the holding member may be a chuck or the like for gripping component 92. Even in such an aspect, effects similar to those of the embodiment are obtained.

In the embodiment, in the calibration processing, jig nozzle 66 is attached to holder 32. On the other hand, in consideration of the fact that there is an individual difference in suction nozzle 33, suction nozzle 33 used for the mounting process scheduled to be executed in the calibration processing may be attached to holder 32.

In the embodiment, bulk feeder 40 supplies a chip component that is rectangular when viewed in the thickness direction as component 92 mounted on board 91 by component mounting machine 10. On the other hand, component 92 is used in a board work machine which executes a predetermined work on board 91 as in component mounting machine 10), and various types of components can be applied as long as the article can be supplied in a state of being accommodated in cavity 51 in bulk feeder 40. For example, bulk feeder 40 may supply a spherical solder ball. Even in such an aspect, effects similar to those of the embodiment are obtained.

### REFERENCE SIGNS LIST

10: Component mounting machine, 12: Component supply device, 122: Feeder, 13: Component transfer device, 20: Control device, 21: Storage section, 22: Mounting control section, 30: Mounting head, 31: Rotary head, 32: Holder, 33: Suction nozzle (Holding member), 40: Bulk feeder, 50: Alignment member, 51: Cavity, 60: Calibration device, 61: Measurement section, 62: Setting section, 91: Board, 92: Component, As: Supply region, Hs: Specified height, Ht: Target height, Nm: Measurement angle, Np: Pickup angle, Ns: Reference angle, Vd: (Height direction) Error, Ve: (Estimated) Error, Mc: Correction value, Ud: Lowering amount, D1: Correction data

1. A component mounting machine comprising:
a mounting head that supports a holding member capable of holding a component to be lifted and lowered and to be rotated about a central axis of the holding member;
a storage section configured to store a correction value for each of multiple measurement angles set based on an error in a height direction when the holding member is moved to a specified height in a state of being indexed to the multiple measurement angles about the central axis; and
a control section configured to correct a lowering amount of the holding member to a target height based on a pickup angle of the holding member indexed about the central axis and the correction value for each of the multiple measurement angles, in a pickup operation of picking up the component by the holding member.

2. The component mounting machine according to claim 1, wherein
the holding member is a suction nozzle holding the component by negative pressure air, and
in the pickup operation, the control section sets a height at which a predetermined clearance is provided from an upper surface of a supplied component as the target height, and sucks and picks up the component by bringing the suction nozzle close to the target height.

3. The component mounting machine according to claim 2, wherein a tip end portion of the suction nozzle is formed in a non-circular shape as viewed in a central axis direction.

4. The component mounting machine according to claim 1, wherein a reference angle and an angle rotated by 90 degrees from the reference angle are included in the multiple measurement angles.

5. The component mounting machine according to claim 1, wherein the storage section stores the lowering amount of the holding member that cancels the error in the height direction as the correction value.

6. The component mounting machine according to claim 1, wherein the control section corrects the lowering amount of the holding member by the correction value of the measurement angle closest to the pickup angle of the holding member.

7. The component mounting machine according to claim 1, wherein the control section estimates a correction value depending on the pickup angle of the holding member based on the correction value for each of the multiple measurement angles and corrects the lowering amount of the holding member.

8. The component mounting machine according to claim 1, wherein
the mounting head supports multiple holding members arranged on the same circumference about an R axis extending in a vertical direction, and
the storage section stores the correction values for each of the multiple holding members and for each of the multiple measurement angles.

9. The component mounting machine according to claim 1, wherein the control section corrects the lowering amount of the holding member based on the correction value in a case of executing the pickup operation of picking up the component from a bulk feeder configured to supply multiple components in a bulk state in a supply region.

10. The component mounting machine according to claim 9, wherein the bulk feeder includes multiple cavities aligned by individually accommodating the multiple components in the bulk state in the supply region.

11. A component-mounting method applied to a component mounting machine including a mounting head that supports a holding member capable of holding a component to be lifted and lowered and to be rotated about a central axis of the holding member, the method comprising:
a storage step of storing a correction value for each of multiple measurement angles set based on an error in a height direction when the holding member is moved to a specified height in a state of being indexed to the multiple measurement angles about the central axis; and
a control step of correcting a lowering amount of the holding member to a target height based on a pickup angle of the holding member indexed about the central axis and the correction value for each of the multiple measurement angles, in a pickup operation of picking up the component by the holding member.

12. A calibration device for a mounting head, the calibration device for being applied to a component mounting machine including a mounting head that supports a holding member capable of holding a component to be lifted and lowered and to be rotated about a central axis of the holding member, the calibration device comprising:
a measurement section configured to measure an error in a height direction when the holding member is moved to a specified height in a state of being indexed to multiple measurement angles about the central axis; and
a setting section configured to set a correction value for each of the multiple measurement angles based on the an error in the height direction.
